(19) United States
(12) Patent Application Publication
(10) Pub. No.: US 2010/0038715 A1
(43) Pub. Date: Feb. 18, 2010

(54) THIN BODY SILICON-ON-INSULATOR TRANSISTOR WITH BORDERLESS SELF-ALIGNED CONTACTS

(75) Inventors: KATHERINA E. BABICH, Chappaqua, NY (US); Michael A. Guillorn, Yorktown Heights, NY (US); Isaac Lauer, White Plains, NY (US); Amlan Majumdar, White Plains, NY (US)

Correspondence Address: FLEIT GIBBONS GUTMAN BONGINI & BIANCO P.L., 551 NW 77TH STREET, SUITE 111, BOCA RATON, FL, 33487, US

(73) Assignee: INTERNATIONAL BUSINESS MACHINES CORPORATION, Armonk, NY (US)

(21) Appl. No.: 12/193,392

(22) Filed: Aug. 18, 2008

(51) Int. Cl. H01L 29/72; H01L 21/84

(52) U.S. Cl. 257/347; 438/151; 257/E29.128

(57) ABSTRACT

A method for fabricating a thin-silicon-on-insulator transistor with borderless self-aligned contacts is disclosed. A gate stack is formed on a silicon layer that is above a buried oxide layer. The gate stack includes a gate oxide layer on the silicon layer and a gate electrode layer on the gate oxide layer. A hard mask on top of the gate stack is formed. An off-set spacer is formed surrounding the gate stack. A raised source/drain region is epitaxially formed adjacent to the off-set spacer. The raised source/drain region is grown slightly about a height of the gate stack including the hard mask. The raised source/drain region forms borderless self-aligned contact.

### FIELD OF THE INVENTION

The present invention generally relates to the field of semiconductors, and more particularly relates to thin body field-effect transistors with electrical contacts on semiconductor substrates.

### BACKGROUND OF THE INVENTION

Complementary Metal Oxide Semiconductor (“CMOS”) Field Effect Transistors (“FETs”) are employed in almost every electronic circuit application, such as signal processing, computing, and wireless communications. One known type of FET is a Silicon-On-Insulator (“SOI”) FET. The formation of electrical contacts to electronic and memory devices is a considerable challenge as the integration density of these devices is increased as a consequence of technology scaling.

For example, the projected contact pitch for 32, 22, and 15 nm nodes are 130, 100, and 80 nm, respectively. In order to fit the contact between adjacent gates, contacts must be made at dimensions approaching the gate length of the device unlike previous technologies where the contacts were many times larger than the gate. Definition of this contact is a lithographic challenge. Alignment of the contact to the source, drain, and gate of the device is critical. In particular, misalignment of the source and drain contacts with respect to the gate can cause electrical shorts, rendering the device inoperable.

### SUMMARY OF THE INVENTION

Briefly, in accordance with the present invention, disclosed in one embodiment is a method for fabricating a thin-silicon-on-insulator transistor with borderless self-aligned contacts is disclosed. The method includes forming a gate stack on a silicon layer that is above a buried oxide layer. The gate stack includes a gate oxide layer on the silicon layer and a gate electrode layer on the gate oxide layer. A hard mask on top of the gate stack is formed. An off-set spacer is formed surrounding the gate stack. A raised source/drain region is epitaxially formed adjacent to the off-set spacer. The raised source/drain region is grown slightly about a height of the gate stack including the hard mask. The raised source/drain region forms borderless self-aligned contact.

In another embodiment a thin-silicon-on-insulator transistor with borderless self-aligned contacts is disclosed. The thin-silicon-on-insulator transistor includes a buried oxide layer above a substrate. A silicon layer overlays the buried oxide layer. A gate stack is situated on the silicon layer. The gate stack includes a gate oxide layer on the silicon layer and a gate electrode on the gate oxide layer. An off-set spacer surrounds the gate stack. Raised source/drain regions each have a first part overlying a portion of the silicon layer, a second part adjacent to off-set spacer, and a third part extending about a top portion of the gate stack.

In yet another embodiment a circuit supporting substrate is disclosed. The circuit supporting substrate includes a thin-silicon-on-insulator transistor with borderless self-aligned contacts. The thin-silicon-on-insulator transistor includes a buried oxide layer above a substrate. A silicon layer overlays the buried oxide layer. A gate stack is situated on the silicon layer. The gate stack includes a gate oxide layer on the silicon layer and a gate electrode on the gate oxide layer. An off-set spacer surrounds the gate stack. Raised source/drain regions each have a first part overlying a portion of the silicon layer, a second part adjacent to off-set spacer, and a third part extending about a top portion of the gate stack.

### BRIEF DESCRIPTION OF THE DRAWINGS

FIGS. 1 to 7 are cross-sectional views of a circuit supporting substrate illustrating a process for forming a thin silicon-on-insulator field-effect transistor with borderless self-aligned electrical contacts according to one embodiment of the present invention.

### DETAILED DESCRIPTION

Embodiments of the present invention provide thin silicon-on-insulator field-effect transistors with borderless self-aligned electrical contacts. Contacts that are self aligned to the source and drain are highly desirable to overcome the misalignment problem discussed above. Generally, an epitaxial layer of Si is grown in the source and drain region of thin body devices, often referred to as a raised source drain (“RSD”). The RSD lowers the external resistance of the device by mitigating the so called “current crowding” effect. It simultaneously provides the requisite volume of Si to form a silicide without fully siliciding the source and drain. The RSD causes an increased capacitance from the source and drain to the gate. This capacitance is present regardless of the gate height.

However, various embodiments of the present invention provide an advantageous method for forming self-aligned borderless contacts to thin body FET devices. These contacts are formed by the epitaxial Si RSD. The RSD process is selective and does not grow on silicon oxide or silicon nitride. By scaling the gate height to match the thickness of the RSD, the parasitic capacitance of the device structure and contacts can be optimized. The RSD-to-gate capacitance remains the same as thin body FET devices fabricated with taller gates. Unlike devices fabricated with taller gates, the capacitance from metal contacts landing on the source and drain is eliminated. This enables more freedom in the design of the contacts to the RSD. Bar contacts can be used without causing a significant increase in the gate to contact capacitance. The RSD can be grown slightly about the height of the gate. This enables the size of the contact made to the RSD to have a relaxed dimension without causing a short to the gate. This type of growth also allows for increased overlay budget in the definition of this contact with respect to the gate.

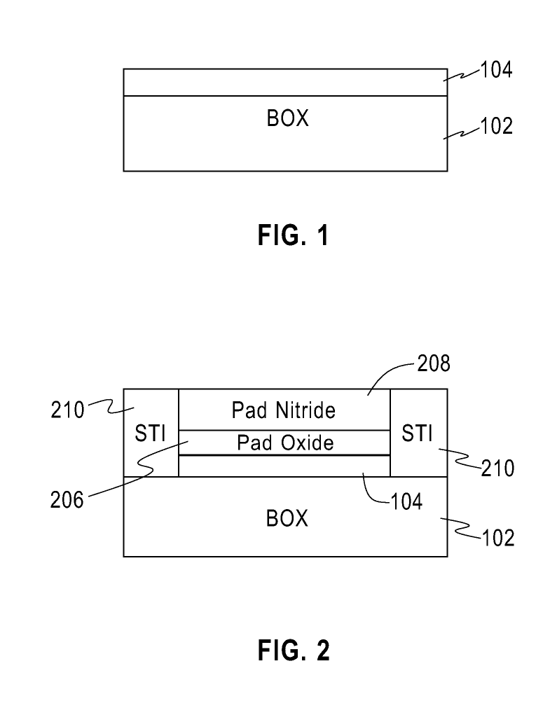

FIGS. 1 to 7 illustrate a process for forming self-aligned borderless contacts to thin body FET devices according to one embodiment of the present invention. The process begins with an SOI wafer that is formed by a silicon substrate (not shown for simplicity), a buried oxide layer (“BOX”) 102 comprising a material such as SiO₂, and a thin SOI layer 104 comprising a material such as Si. The thin SOI layer 104 can have any thickness that is suitable for building short gate length devices.

The SOI layer 104 is patterned into discrete islands to form individual transistors. The discrete SOI islands are electrically isolated by the BOX layer 102. In addition, the BOX layer 104 can be recessed and a dielectric material can be used to form a shallow trench isolation. For example, FIG. 2 shows a process for defining an active area for a transistor. In this embodiment, the active area is defined through pad-film deposition, photolithography, and reactive-ion etching (“RIE”). However, the present invention is not limited to these techniques. In particular, a pad oxide 206 (e.g., having a thickness of 2-10 nm) is formed in a conventional oxidation furnace, and a pad nitride 208 (e.g., having a thickness of 30-150 nm) is deposited using low-pressure chemical vapor deposition (“LPCVD”) or rapid-thermal chemical vapor deposition (“RTCVD”). Photolithography and a nitride-oxide-silicon RIE are then performed to define the active area.

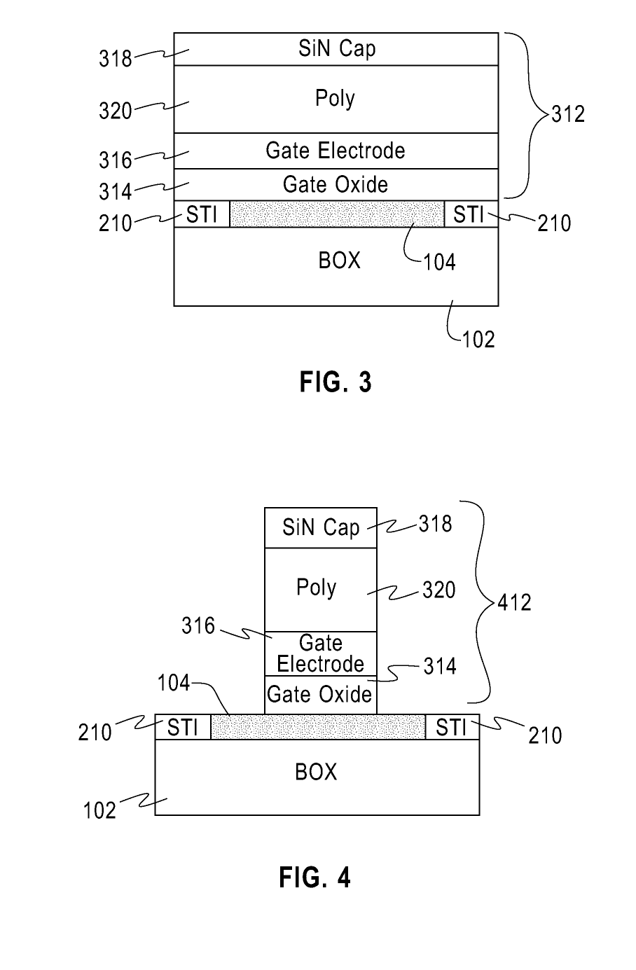

Next, the active area is optionally isolated, such as through shallow trench isolation (“STI”). In this embodiment, STI is obtained through deposition of an STI oxide/dielectric, densification anneals, and chemical-mechanical polishing (“CMP”) that stops on the pad nitride 208. This forms an STI region 210 over the BOX layer 102 that is continuous around the active area, as shown in FIG. 1. The pad nitride 208, along with any STI oxide remaining on the pad nitride 208, and the pad oxide 206 are then removed (e.g., through wet etching using hot phosphoric acid and HF), as shown in FIG. 3.

A gate stack 312 is deposited onto the SOI layer 104. This gate stack 312 is composed of a gate oxide 314, a gate electrode 316, and a SiN-based hardmask 318, as shown in FIG. 3. The gate oxide 314 can be (but not limited to) SiO2, SiON, or a metal oxide such as (but not limited to) HfO₂, HfSiOₓ, HfSiOₓN_{y}, Ta₂O₅, TiO₂, Al₂0₃, Y₂O₃ and La₂O₅. In some embodiments, the metal oxide creates a high-k layer. The material comprising the gate electrode 316 is determined by the choice of the gate oxide 314. For example, in the case of Si-based oxides, polysilicon can be used. In the case of metal oxides, a metal can be used such as (but not limited to) TiN, Ta, TaN, TaCN, TaSiN, TaSi, AlN, W and Mo. The gate oxide 314 and gate electrode 316 can be deposited using any conventional deposition process such metal-organic chemical vapor deposition (“MOCVD”) or atomic-layer deposition (“ALD”) and physical vapor deposition (“PVD”), MOCVD, or ALD, respectively.

The gate stack 312 can also include an optional deposition of an amorphous Si or a poly Si layer 320, which is deposited using conventional processes such as LPCVD or silicon sputtering. The silicon nitride cap 318 is deposited to allow the later formation of a silicon (or SiGe) raised source/drain through epitaxy. In particular, the nitride cap 318 protects the polysilicon gate during epitaxy to avoid forming an unwanted polysilicon (or poly-SiGe, also referred to as a mushroom) on the gate electrode, which would adversely affect transistor performance as well as transistor yield. (In some embodiments, an oxide cap is deposited to act as a hardmask for gate etch.)

The transistor gate is then defined using photolithography, RIE, and wet cleaning, as shown in FIG. 4. The wet cleaning removes any polymers formed during the RIE and an oxide cap if one was previously formed on top of the nitride cap 318. As shown in FIG. 4, the resulting gate stack 412 is formed by the gate oxide layer 314, the gate electrode 316, the optional polysilicon cap layer 320, and the silicon nitride cap layer 320.

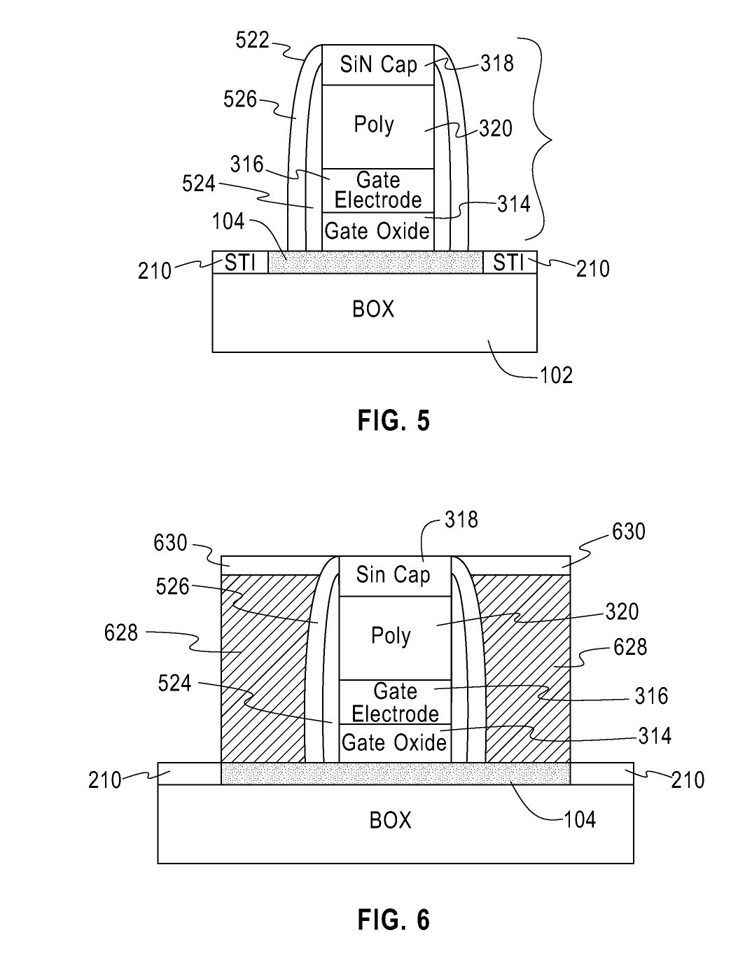

An offset spacer 522 is formed using a combination of thin film deposition and etching, as shown in FIG. 5. The spacer 522 can include two or more layers 524, 526. For example, the layers 524, 526 can be a thin silicon oxide layer 524 followed by a thin SiN layer 526. The SiN layer 526, in one embodiment, prevents unwanted epitaxial growth on the sidewall of the gate 412. If silicon oxide is used alone it will be attacked by the epitaxial growth preclean, which etches oxide. It should be noted that the outer layer 526 can be replaced by any suitable dielectric material that can withstand the epitaxial preclean process. Also, the etching of the spacer 522, in one embodiment, is performed so as to not expose the gate 316. This can be done by minimizing the over etch, keeping the spacer 522 from pulling down below the thickness of the nitride hard mask 318

Once the spacer 522 has been at least partially completed, ion implantation can be performed to provide extension doping. For example, halo and source/drain extensions are formed through implantation. Photolithography is used to selectively define the NFET and PFET areas for source/drain extension and halo implants, and then ions are implanted. For an NFET, the halo implants are performed with a p-type species such as B, BF₂, or In and the extension implants are performed with an n-type species such as As, P, or Sb. For a PFET, the halo implants are performed using an n-type species As, P, or Sb, and the extension implants are performed using p-type species such as B, BF₂. An anneal (e.g., millisecond laser anneal or flash anneal) is performed after implantation to heal the damage to the thin SOI layer due to ion implantation. This annealing process also activates the halo and extension implants without diffusing them into the buried oxide layer 104. Diffusion of the halo or extension implants would degrade performance due to dose loss into the underlying buried oxide layer.

Raised source/drain growth is then performed to create a raised source/drain 628, as shown in FIG. 6. This process can include the incorporation of dopant gases and can be performed at sufficiently low temperatures, pressures and gas flows to prevent agglomeration of the patterned SOI 104. The raised source/drain 628 acts as a borderless self-aligned contact to the source and drain. The raised source/drain 628, in one embodiment, is formed using epitaxy.

To form the raised source/drain 628, an initial pre-cleaning removes any oxide and liners and exposes the silicon surface 104 in the source/drain areas. In this embodiment, the pre-cleaning is performed using an HF wet etch or HF-vapor based chemical oxide removal (“COR”). Next, epitaxy that is selective with respect to oxide and nitride is used to form the raised source/drain 1446, so there is no deposition on the nitride cap 318, the oxide and SiN spacers 524, 526, and the optional STI oxide 210. In this embodiment, the raised source/drain 628 is formed of silicon (or SiGe or SiC or SiGeC). Dopants can be introduced into the epitaxial growth to produce in situ source/drain regions. For example, by mixing dilute phosphine into the growth gasses, N type source/drain regions will be produced. Likewise, the incorporation of diborane during growth creates P type source/drain regions. This type of processing eliminates the need for further ion implantation.

If in situ doping is not used during the time of RSD formation, deep source/drain implantation is performed. In this embodiment, the deep implantation is done by using photolithography to selectively define NFET and PFET areas for deep source/drain implants, and then ions are implanted. N-type species are implanted for NFETs, while p-type species are implanted for PFETs. A thermal anneal is then performed to activate and diffuse the ions that have been implanted.

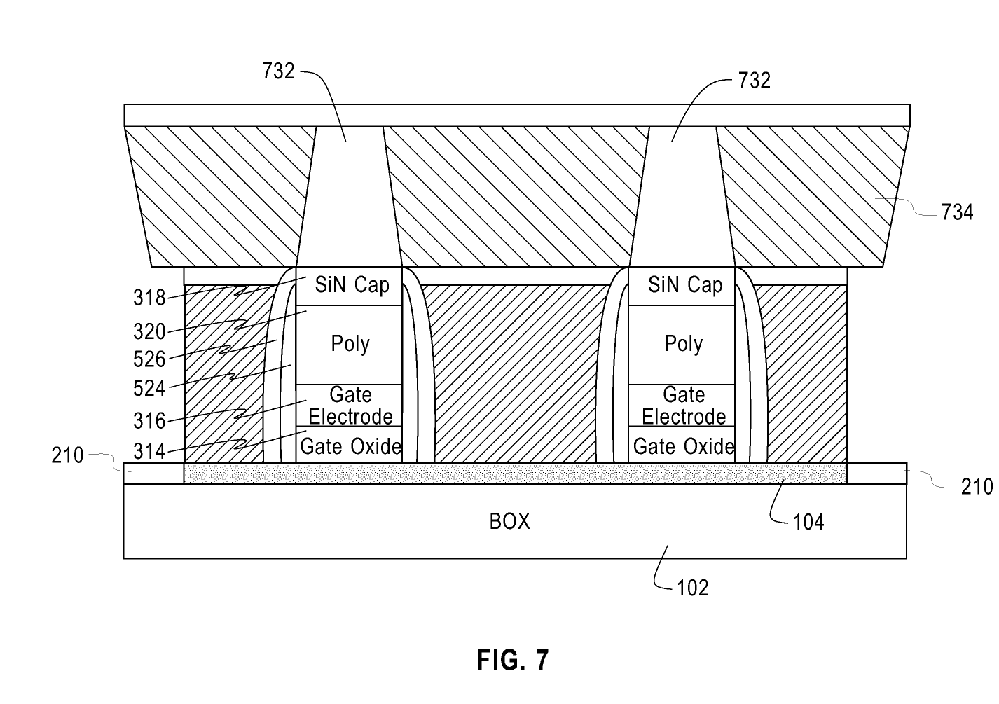

Next, silicide areas 620 and 620 are formed for contacts. In this embodiment, this is achieved by removing the oxide (e.g., through a wet etch using HF), depositing a metal, performing an anneal to form silicide, and then selectively removing the metal but leave the silicide untouched (e.g., through an aqua regia wet etch). In this exemplary embodiment, the metal is NiPt, CoSi2, or the like. A dielectric layer 732 is deposited onto the substrate and then planarized as shown in FIG. 7.

Contacts 734 to the RSD 628 are created using lithography and RIE followed by metallization. The metallization can involve CVD, PVD, ALD, or electroplating processes or some combination of these processes. The contacts 734 can be defined as to overlap the gate stack 412, as shown in FIG. 7. The remaining nitride hard mask 318 on the gate prevents the RIE process from shorting the contact to the gate electrode 316.

As can be seen, self-aligned borderless contacts are created by the epitaxial Si RSD. The RSD process is selective and does not grow on silicon oxide or silicon nitride. By scaling the gate height to match the thickness of the RSD, the parasitic capacitance of the device structure and contacts can be optimized. The RSD-to-gate capacitance remains the same as thin body FET devices fabricated with taller gates. Unlike devices fabricated with taller gates, the capacitance from metal contacts landing on the source and drain is eliminated. This enables more freedom in the design of the contacts to the RSD. Bar contacts can be used without causing a significant increase in the gate to contact capacitance. The RSD can be grown slightly about the height of the gate. This enables the size of the contact made to the RSD to have a relaxed dimension without causing a short to the gate. This type of growth also allows for increased overlay budget in the definition of this contact with respect to the gate.

It should be noted that some of the features of the examples of this invention may be used to advantage without the corresponding use of other features. As such, the foregoing description should be considered as merely illustrative of the principles, teachings, examples, and exemplary embodiments of this invention, and not in limitation thereof.

It should be understood that these embodiments are only examples of the many advantageous uses of the innovative teachings herein. In general, statements made in the specification of the present application do not necessarily limit any of the various claimed inventions. Moreover, some statements may apply to some inventive features but not to others. In general, unless otherwise indicated, singular elements may be in the plural and vice versa with no loss of generality.

The circuit as described above is part of the design for an integrated circuit chip. The chip design is created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The method as described above is used in the fabrication of integrated circuit chips. The resulting integrated circuit chips can be distributed by the fabricator in raw wafer form (that is, as a single wafer that has multiple unpackaged chips), as a bare chip, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard, or other input device, and a central processor.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments, and it is intended that the appended claims cover any and all such applications, modifications, and embodiments within the scope of the present invention.

What is claimed is:

1. A method for fabricating a thin-silicon-on-insulator transistor with borderless self-aligned contacts, the method comprising the steps of:
forming a gate stack on a silicon layer that is above a buried oxide layer, the gate stack including gate oxide layer on the silicon layer and a gate electrode layer on the gate oxide layer;
forming a hard mask on top of the gate stack;
forming an off-set spacer surrounding the gate stack; and
epitaxially forming a raised source/drain region adjacent to the off-set spacer, wherein the raised source/drain region is grown slightly about a height of the gate stack including the hard mask, wherein the raised source/drain region forms borderless self-aligned contact.

2. The method of claim 1, wherein forming an off-set spacer surrounding the gate stack further comprises:
forming a first layer of an oxide material surrounding the gate stack; and
forming a second layer of silicon nitride surrounding the first layer.

3. The method of claim 1, wherein the gate oxide layer is a high-k oxide layer, and wherein the gate electrode layer is a metal gate layer.

4. The method of claim 1, further comprising:
forming a silicide area on the raised source/drain region.

5. The method of claim 4, further comprising:
depositing dielectric layer over the raised source/drain region and the silicide area; and
planarizing the dielectric area.

6. The method of claim 5, further comprising:
forming contacts areas through the dielectric layer corresponding to the silicide area; and
metalizing the contact areas thereby creating a metal contact that contacts the silicide area.

7. The method of claim 6, wherein the contact area partially overlaps the gate stack.

8. A thin-silicon-on-insulator transistor with borderless self-aligned contacts comprising:
a buried oxide layer above a substrate;
a silicon layer above the buried oxide layer;
a gate stack on the silicon layer, the gate stack including a gate oxide layer on the silicon layer and a gate electrode on the gate oxide layer;
an off-set spacer surrounding the gate stack; and
raised source/drain regions each having a first part overlying a portion of the silicon layer, a second part adjacent to off-set spacer, and a third part extending about a top portion of the gate stack.

9. The thin-silicon-on-insulator transistor of claim 8, further comprising:
a silicide layer extending into the third part of the raised source/drain regions.

10. The thin-silicon-on-insulator transistor of claim 9, further comprising:
a planarized dielectric layer overlaying the raised source/drain regions and the silicide layer.

11. The thin-silicon-on-insulator transistor of claim 10, further comprising:
contact areas formed through the dielectric layer corresponding to the silicide layer.

12. The thin-silicon-on-insulator transistor of claim 11, wherein the contact areas comprise:
metalized contacts that contact that substantially contact the silicide layer.

13. The thin-silicon-on-insulator transistor of claim 11, wherein the contact area partially overlaps the gate stack.

14. The thin-silicon-on-insulator transistor of claim 8, wherein the off-set spacer further comprises:
a first layer of an oxide material surrounding the gate stack; and
a second layer of silicon nitride surrounding the first layer.

15. The thin-silicon-on-insulator transistor of claim 8, wherein the gate oxide layer is a high-k oxide layer, and wherein the gate electrode layer is a metal gate layer.

16. A circuit supporting substrate comprising:
a thin-silicon-on-insulator transistor, wherein the thin-silicon-on-insulator transistor comprises:
a buried oxide layer above a substrate;
a silicon layer above the buried oxide layer;
a gate stack on the silicon layer, the gate stack including a gate oxide layer on the silicon layer and a gate electrode on the gate oxide layer;
an off-set spacer surrounding the gate stack; and
raised source/drain regions each having a first part overlying a portion of the silicon layer, a second part adjacent to off-set spacer, and a third part extending about a top portion of the gate stack.

17. The circuit supporting substrate of claim 16, wherein the thin-silicon-on-insulator transistor further comprises:
a silicide layer extending into the third part of the raised source/drain regions.

18. The circuit supporting substrate of claim 17, wherein the thin-silicon-on-insulator transistor further comprises:
contact areas formed through a planarized dielectric layer overlaying the raised source/drain regions and the silicide layer dielectric layer corresponding to the silicide layer, wherein the contact areas define borderless self-aligned contacts.

19. The circuit supporting substrate of claim 18, wherein contact areas comprise:
metalized contacts that contact that substantially contact the silicide layer.

20. The circuit supporting substrate of claim 18, wherein the contact area partially overlaps the gate stack.
